(19) United States
(12) Patent Application Publication
(10) Pub. No.: US 2026/0282426 A1
(43) Pub. Date: Sep. 17, 2026

(54) SEMICONDUCTOR DEVICE AND METHOD FOR MANUFACTURING SEMICONDUCTOR DEVICE

(71) Applicants: DENSO CORPORATION, Kariya-shi (JP); TOYOTA JIDOSHA KABUSHIKI KAISHA, Toyota-shi (JP); MIRISE Technologies Corporation, Nisshin-shi (JP)

(72) Inventors: Aiko ICHIMURA, Nisshin-shi (JP); Jun SAITO, Nisshin-shi (JP)

(21) Appl. No.: 19/543,070

(22) Filed: Feb. 18, 2026

(30) Foreign Application Priority Data
Mar. 12, 2025 (JP) 2025-039521

(51) Int. Cl. H10D 30/62; H10P 30/20; H10P 50/00

(52) U.S. Cl. CPC H10D 30/6212; H10P 30/208; H10P 50/69

(57) ABSTRACT

A semiconductor device includes a semiconductor substrate, a gate insulating film and a gate electrode. The semiconductor substrate has a support layer and a fin. The fin protrudes from an upper surface of the support layer and extends along a predetermined direction. The gate insulating film covers a surface of the fin. The gate electrode covers the gate insulating film. The fin has a step portion on a side surface, and a width of the fin is different above and below the step portion.

### CROSS REFERENCE TO RELATED APPLICATION

The present application claims the benefit of priority from Japanese Patent Application No. 2025-039521 filed on Mar. 12, 2025, and the entire disclosure of which is incorporated herein by reference.

### TECHNICAL FIELD

The present disclosure relates to a semiconductor device and a method for manufacturing a semiconductor device.

### BACKGROUND

An example of a fin-type semiconductor device is a fin field-effect transistor (FinFET). Such a semiconductor device has a semiconductor substrate, a gate insulating film, and a gate electrode. The semiconductor substrate has a support layer and a fin protruding from an upper surface of the support layer. The gate insulating film covers a surface of the fin. The gate electrode faces the fin with the gate insulating film interposed therebetween. Further, the semiconductor substrate is provided with a source region and a drain region connected to the source region via the fin.

In such a semiconductor device, the surface of the fin protruding from the support layer is covered by the gate electrode. In such a configuration, when the semiconductor device turns on, a channel is formed in substantially the entire area of the fin, so that a large current can flow between the source region and the drain region.

### SUMMARY

According to an aspect of the present disclosure, a semiconductor device includes a semiconductor substrate, a gate insulating film and a gate electrode. The semiconductor substrate has a support layer and a fin. The fin protrudes from an upper surface of the support layer and extends along a predetermined direction. The gate insulating film covers a surface of the fin. The gate electrode covers the gate insulating film. The fin may have a step portion on a side surface, and a width of the fin may differ above and below the step portion.

### BRIEF DESCRIPTION OF DRAWINGS

FIG. 1 is a perspective view showing a schematic configuration of a semiconductor device according to a first embodiment.

FIG. 2 is a cross-sectional view taken along a line II-II in FIG. 1.

FIG. 3 is a cross-sectional view taken along a line III-III in FIG. 1.

FIG. 4 is a diagram for explaining a manufacturing process of the semiconductor device.

FIG. 5 is a diagram for explaining a manufacturing process of the semiconductor device.

FIG. 6 is a diagram for explaining a manufacturing process of the semiconductor device.

FIG. 7 is a diagram for explaining a manufacturing process of the semiconductor device.

FIG. 8 is a diagram for explaining a manufacturing process of the semiconductor device.

FIG. 9 is a diagram for explaining a manufacturing process of the semiconductor device.

FIG. 10 is a diagram for explaining a manufacturing process of the semiconductor device.

FIG. 11 is a diagram for explaining a manufacturing process of the semiconductor device.

FIG. 12 is a cross-sectional view, taken at a position corresponding to FIG. 2,

of a semiconductor device according to a second embodiment.

FIG. 13 is a cross-sectional view, taken at a position corresponding to FIG. 2, of a semiconductor device according to a third embodiment.

### DETAILED DESCRIPTION

When a semiconductor device operates, the temperature of the semiconductor device changes. Since the coefficients of linear expansion of respective members constituting the semiconductor device are different, thermal stress is generated inside the semiconductor device when the temperature of the semiconductor device changes. In a fin-type semiconductor device, since the fin is extremely thin, it is easily deformed by thermal stress generated by expansion and contraction of the gate insulating film and the gate electrode. If the fin is deformed, there is a possibility that a leakage current may flow in the semiconductor device. The present disclosure provides a semiconductor device, which is capable of suppressing deformation of a fin due to thermal stress, and a method for manufacturing the semiconductor device.

According to an aspect of the present disclosure, a semiconductor device includes a semiconductor substrate, a gate insulating film, and a gate electrode. The semiconductor substrate has a support layer and a fin that protrudes from an upper surface of the support layer and extends along a predetermined direction. The gate insulating film covers a surface of the fin. The gate electrode covers the gate insulating film. A side surface of the fin has a step portion, and a width of the fin differs above and below the step portion.

In such a semiconductor device, the side surface of the fin has the step portion, and the width of the fin differs between the upper side and the lower side of the step portion. In other words, the fin has a wide portion with a large width and a narrow portion with a small width, and one of the wide portion and the narrow portion is above the step portion, and the other is below the step portion. Since the fin has the wide portion, the strength of the fin against a force applied in the width direction of the fin is increased, for example, compared to a fin having a constant width from top to bottom. Therefore, even if a large thermal stress is generated, the fin is less likely to deform.

According to an aspect of the present disclosure, a method for manufacturing a semiconductor device, includes: forming a high crystal defect density region having an increased crystal defect density in a specific depth range of a semiconductor substrate by ion-implanting an impurity from an upper surface of the semiconductor substrate into the specific depth range, so that a low crystal defect density region having a crystal defect density lower than that of the high crystal defect density region exists on at least one of an upper side and a lower side of the high crystal defect density region in the semiconductor substrate; forming a mask having a plurality of openings on the upper surface of the semiconductor substrate such that each of the openings is located above the high crystal defect density region; and forming a plurality of recesses in a depth range spanning the high crystal defect density region and the low crystal defect density region by etching the upper surface of the semiconductor substrate through the plurality of openings, such that a fin is formed between the plurality of recesses.

In such a manufacturing method, the high crystal defect density region is formed in the semiconductor substrate such that the high crystal defect density region and the low crystal defect density region are arranged along a vertical direction. Then, the plurality of recesses are formed by etching through the plurality of openings in a depth range spanning the high crystal defect density region and the low crystal defect density region. The high crystal defect density region has a higher etching rate compared to the low crystal defect density region. Therefore, in a depth range where the high crystal defect density region exists, the width of the formed recess becomes wider than in a depth range where the low crystal defect density region exists. In other words, in the depth range where the high crystal defect density region exists, the width of the fin formed between the plurality of recesses becomes narrower than in the depth range where the low crystal defect density region exists. Thus, in the above manufacturing method, the boundary between the depth range where the high crystal defect density region exists and the depth range where the low crystal defect density region exists results in the step portion of the fin, so that the fin having different widths on the upper side and the lower side of the step portion can be formed.

In an embodiment of the present disclosure, the width of the fin at portion between the upper surface of the support layer and the step portion may be wider than the width of the fin at a portion above the step portion.

A large thermal stress is likely to be applied to a connection portion between the fin and the support layer. According to a configuration described above, since the width of the fin at the connection portion with the support layer is wide, deformation of the fin can be suppressed even if a large thermal stress is generated.

In an embodiment of the present disclosure, the width of the fin at a portion between an upper end of the fin and the step portion may be wider than the width of the fin at a portion below the step portion.

An upper end portion of the fin is easily deformed by thermal stress. According to a configuration described above, since the width of the fin at the upper end portion is wide, deformation of the fin can be suppressed even if a large thermal stress is generated.

In an embodiment of the present disclosure, the step portion may have a first step portion and a second step portion located above the first step portion. The width of the fin at a portion between the upper surface of the support layer and the first step portion may be wider than the width of the fin at a portion between the first step portion and the second step portion, and the width of the fin at the portion between the first step portion and the second step portion may be narrower than the width of the fin at a portion above the second step portion.

According to such a configuration, since the width of the fin at the connection portion with the support layer and the width of the fin at the upper end portion are wide, deformation of the fin can be suppressed even if a large thermal stress is generated.

In an embodiment the present disclosure, a minimum width of the fin may be 300 nm or less.

According to such a configuration, when the semiconductor device turns on, most of the fin can function as a channel.

Hereinafter, embodiments of the present disclosure will be described more in detail with reference to the drawings.

### First Embodiment

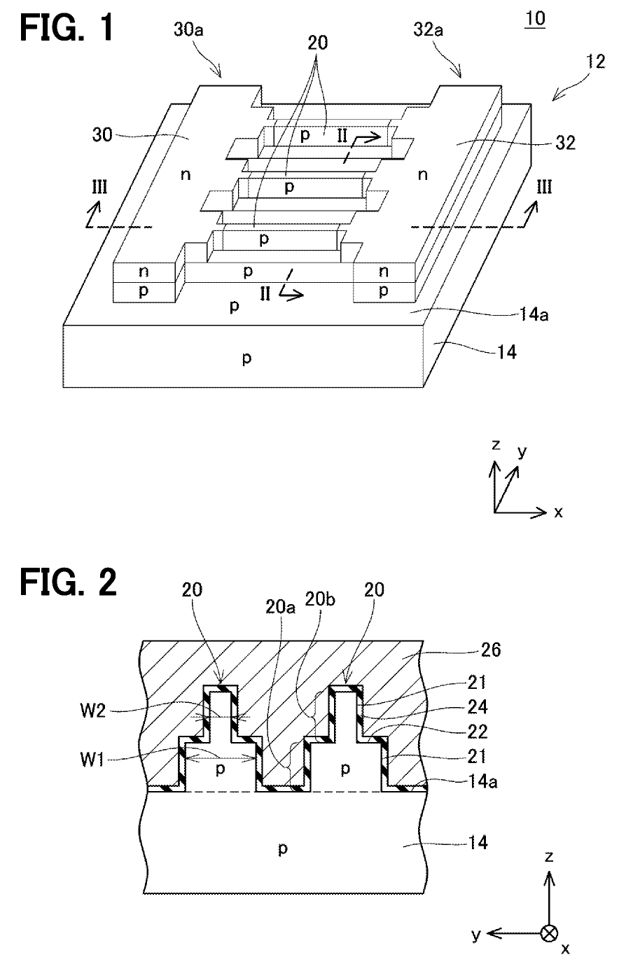

With reference to FIGS. 1 to 3, a semiconductor device 10 of a first embodiment will be described, as an example. FIG. 1 schematically shows a three-dimensional configuration of the semiconductor device 10. The semiconductor device 10 is a fin field-effect transistor (FinFET), and has a semiconductor substrate 12. The semiconductor substrate 12 is made of silicon carbide (SiC). However, the material of the semiconductor substrate 12 is not particularly limited, and may be other semiconductor materials such as silicon (Si), gallium nitride (GaN), and gallium oxide (Ga₂O₃).

As shown in FIG. 1, the semiconductor substrate 12 has a support layer 14, a plurality of fins 20, a source region 30, and a drain region 32. The support layer 14 has a plate shape. Therefore, an upper surface 14a of the support layer 14 is flat. Hereinafter, one direction parallel to the upper surface 14a of the support layer 14 is referred to as an x-direction, a direction parallel to the upper surface 14a of the support layer 14 and orthogonal to the x-direction is referred to as a y-direction, and a thickness direction of the support layer 14 is referred to as a z-direction. In this example, an example in which three fins 20 are provided is shown, but the number of fins 20 is not particularly limited. The number of fins 20 may be one, two, or four or more.

As shown in FIGS. 1 and 2, a plurality of fins 20 protrude upward from the upper surface 14a of the support layer 14. The plurality of fins 20 are arranged at intervals in the y-direction. Each fin 20 extends long along the x-direction. Note that the ”fin” in this specification means a structure satisfying the relationship of L > H > W, where L is a length in the x-direction, H is a height from the upper surface 14a of the support layer 14 to an upper end, and W is a width in the y-direction.

As shown in FIG. 2, a side surface 21 of each fin 20 has a step portion 22. The width of the fin 20 is different between the upper side of the step portion 22 and the lower side of the step portion 22. In this example, a width W1 of the fin 20 from the upper surface 14a of the support layer 14 to the step portion 22 (hereinafter referred to as a wide portion 20a) is wider than a width W2 of the fin 20 from the step portion 22 to the upper end of the fin 20 (hereinafter referred to as a narrow portion 20b). The wide portion 20a extends upward from the upper surface 14a of the support layer 14 to the step portion 22 with a substantially constant width W1. The narrow portion 20b extends upward from the step portion 22 to the upper end of the fin 20 with a substantially constant width W2. The width of each fin 20 in the y-direction is not particularly limited, but for example, the width of the narrow portion 20b in the y-direction can be 300 nm or less.

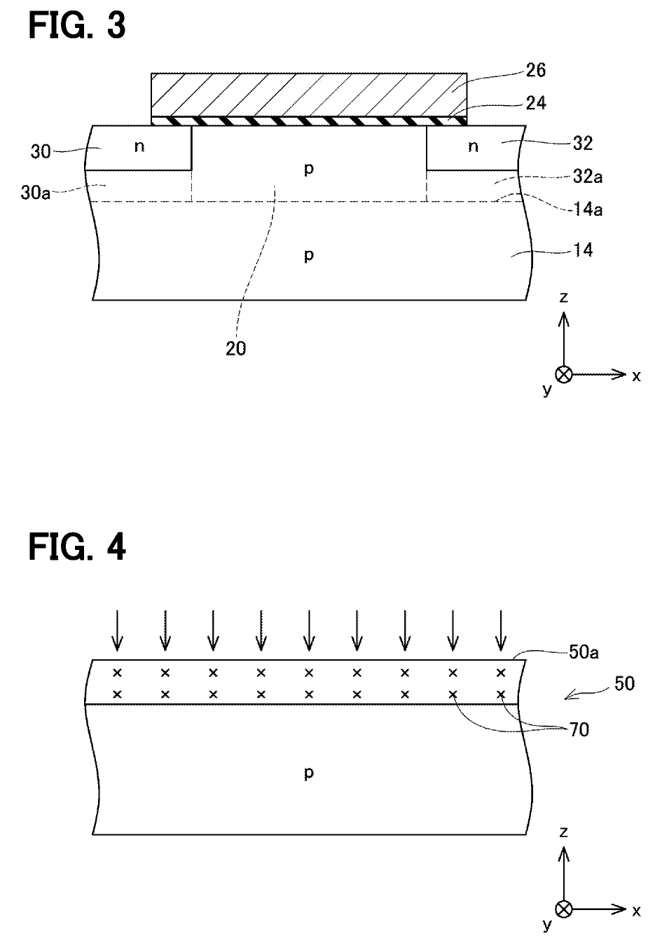

As shown in FIGS. 1 and 3, the semiconductor substrate 12 has protruded portions 30a and 32a protruding upward from the upper surface 14a of the support layer 14. The protruded portion 30a is connected to one end of each fin 20 in the x-direction. The protruded portion 32a is connected to the other end of each fin 20 in the x-direction. That is, the protruded portion 30a and the protruded portion 32a are connected to each other via the plurality of fins 20.

As shown in FIGS. 2 and 3, the semiconductor device 10 further includes a gate insulating film 24 and a gate electrode 26. The gate insulating film 24 covers the upper surface 14a of the support layer 14 and the surface of each fin 20. The gate insulating film 24 is made of, for example, silicon oxide (SiO₂). As shown in FIG. 3, the gate insulating film 24 covers a range spanning from the surface of each fin 20 to a part of the surface of the source region 30 and a part of the surface of the drain region 32. The gate electrode 26 is disposed on an upper part of the gate insulating film 24. The gate electrode 26 is disposed to extend over upper parts of the plurality of fins 20. The gate electrode 26 covers the gate insulating film 24. The gate electrode 26 is made of, for example, polysilicon (poly-Si).

In FIG. 1, illustration of the gate insulating film 24 and the gate electrode 26 is omitted for ease of viewing the drawing. Further, in FIGS. 1 to 3, illustration of structures (for example, insulating layers, etc.) provided above the semiconductor substrate 12 and above the gate electrode 26, a source electrode in contact with the source region 30, a drain electrode in contact with the drain region 32, and the like is omitted.

As shown in FIGS. 1 and 3, the semiconductor substrate 12 has a source region 30 of an n-type, a drain region 32 of an n-type, and a p-type region. The source region 30 is provided in an upper portion of the protruded portion 30a. The source region 30 is disposed to extend from the protruded portion 30a to the end of each fin 20. The drain region 32 is provided in an upper portion of the protruded portion 32a. The drain region 32 is distributed from the protruded portion 32a to the end of each fin 20.

The p-type region is provided in each fin 20, the protruded portions 30a and 32a, and the support layer 14. In a portion of each fin 20 above the step portion 22, the entire region between the source region 30 and the drain region 32 is the p-type region. In a portion below the step portion 22, the p-type region is distributed spanning across each fin 20, the protruded portions 30a and 32a, and the support layer 14. The source region 30 is separated from the drain region 32 by the p-type region.

Next, the operation of the semiconductor device 10 will be described. When the semiconductor device 10 is used, a voltage is applied in a direction such that the drain region 32 side has a higher potential than the source region 30 side. When turning on the semiconductor device 10, the potential of the gate electrode 26 is raised to a potential higher than a gate threshold. Since the gate electrode 26 is provided at a position facing both side surfaces of each fin 20, in the process of raising the potential of the gate electrode 26, the vicinity of both side surfaces of each fin 20 is inverted from p-type to n-type. In this example, the width of the narrow portion 20b of each fin 20 is 300 nm or less. Since the width of the narrow portion 20b is sufficiently narrow, when the potential of the gate electrode 26 is further raised, an inversion layer spreads to the inside of the narrow portion 20b, and substantially the entire area of the narrow portion 20b connecting the source region 30 and the drain region 32 is inverted to n-type. Thus, a channel is formed in substantially the entire area within the narrow portion 20b. The source region 30 and the drain region 32 are connected by this channel. Therefore, electrons flow from the source region 30 to the drain region 32 via the channel. In this way, the semiconductor device 10 turns on. In this semiconductor device 10, since the channel is formed in a wide range within the fin 20, low channel resistance can be realized. When turning off the semiconductor device 10, a potential lower than the gate threshold is applied to the gate electrode 26. Thus, the channel formed inside the fin 20 disappears, and the semiconductor device 10 turns off.

When the semiconductor device 10 operates, the temperature of the semiconductor device 10 changes. Since the coefficients of linear expansion of respective members constituting the semiconductor device 10 are different, thermal stress is generated inside the semiconductor device 10 when the temperature of the semiconductor device 10 changes. Since each fin 20 has a thin plate shape, it is easily affected by thermal stress applied by expansion and contraction of the adjacent gate electrode 26 and the like. In particular, a large thermal stress is likely to be applied to the connection portion between the fin 20 and the support layer 14. If the fin 20 is deformed so as to tilt in the y-direction due to the thermal stress, there is a possibility that a leakage current may occur to flow in the semiconductor device 10.

However, in the semiconductor device 10 of this example, the fin 20 has the wide portion 20a having a large width in the y-direction extending from the upper surface 14a of the support layer 14 to the step portion 22. That is, in this example, the width of the connection portion between the fin 20 and the support layer 14 is increased. Therefore, the fin 20 has high strength against a force applied in the y-direction. As such, even if a large thermal stress is generated, it is possible to suppress deformation of the fin 20 such that it tilts with respect to the upper surface 14a of the support layer 14.

In the above-described example, the width of the narrow portion 20b of each fin 20 does not have to be 300 nm or less. Further, in the above-described example, the step portions 22 are provided on both sides of the side surface 21 of the fin 20. As another example, the step portion 22 may be provided on only one side of the fin 20. The same applies to second and third embodiments, which will be described later.

Next, with reference to FIGS. 4 to 11, a method for manufacturing the semiconductor device 10 of the first embodiment will be described. The method for manufacturing the semiconductor device 10 is characterized by a process of forming the plurality of fins 20. Hereinafter, the process of forming the plurality of fins 20 will be mainly described, and description of other manufacturing processes will be omitted.

FIGS. 4 to 6 are views corresponding to the cross-section shown in FIG. 3. First, as shown in FIG. 4, a p-type semiconductor substrate 50 is prepared. An n-type impurity is ion-implanted from an upper surface 50a of the semiconductor substrate 50 into substantially the entire area of the upper surface 50a. The n-type impurity is implanted into a depth range that will later become the source region 30 and the drain region 32. By the implantation of the n-type impurity, crystal defects 70 are generated inside the semiconductor substrate 50.

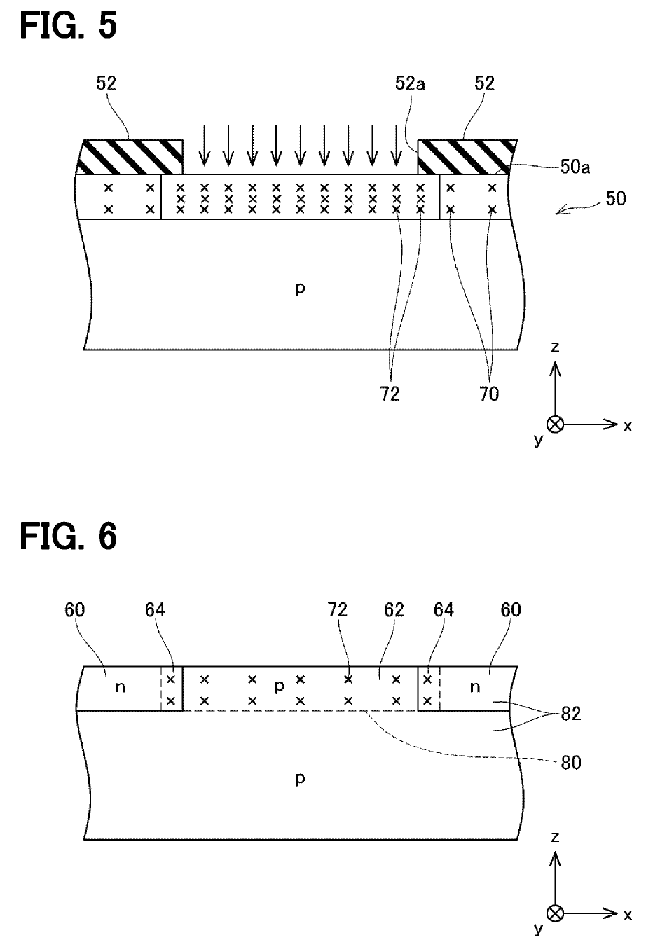

Next, as shown in FIG. 5, a mask 52 having an opening 52a is formed on the upper surface 50a of the semiconductor substrate 50. Here, the mask 52 is formed such that the opening 52a is located above a range corresponding to the region between the source region 30 and the drain region 32 shown in FIG. 3. Then, a p-type impurity is ion-implanted from the upper surface 50a of the semiconductor substrate 50 into the semiconductor substrate 50 through the mask 52. The p-type impurity is implanted into the depth range into which the n-type impurity has been implanted. Further, the p-type impurity is implanted so as to have a higher concentration than the n-type impurity implanted in the process shown in FIG. 4. By the implantation of the p-type impurity, crystal defects 72 are generated inside the semiconductor substrate 50. The crystal defects 72 in the region where the p-type impurity is implanted are more numerous than the crystal defects 70 in the region where only the n-type impurity is implanted. In this process, the p-type impurity is implanted into a range wider than the width of the opening 52a of the mask 52 due to lateral diffusion of the p-type impurity. That is, the crystal defects 72 spread over a range wider than the opening 52a of the mask 52.

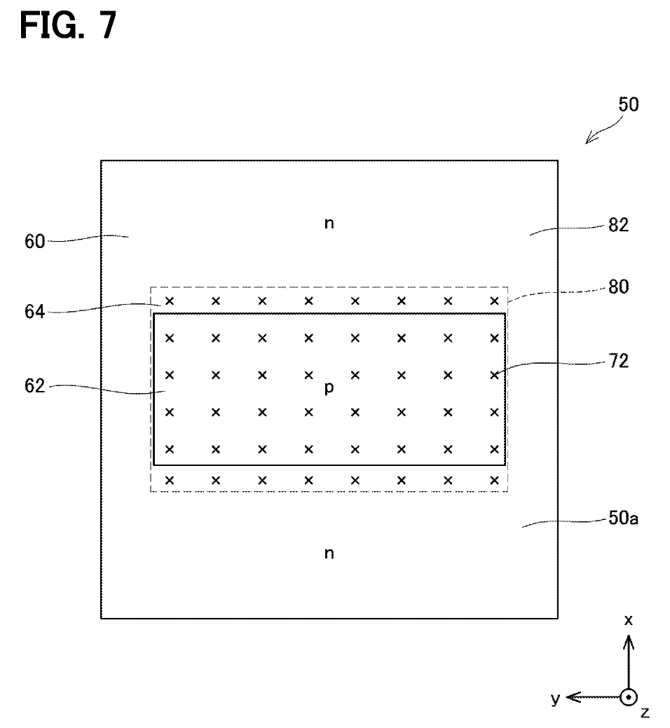

Next, the mask 52 is removed, and the semiconductor substrate 50 is annealed. Thus, the n-type impurity and the p-type impurity implanted into the semiconductor substrate 50 are activated. As shown in FIG. 6, in the region where only the n-type impurity has been implanted, an n-type region 60 is formed inside the semiconductor substrate 50. On the other hand, in the region where the n-type impurity and the p-type impurity have been implanted, since the concentration of the p-type impurity is higher than the concentration of the n-type impurity, a p-type region 62 is formed inside the semiconductor substrate 50. Further, in the process of implanting the p-type impurity, in a region where the p-type impurity has diffused outside the opening 52a of the mask 52, since the diffusion amount of the p-type impurity is small, the concentration of the p-type impurity is lower than that of the n-type impurity. Therefore, an n-type region 64 is formed inside the semiconductor substrate 50. As described above, the crystal defects 72 in the region where the p-type impurity has been implanted are more numerous than the crystal defects 70 in the region where only the n-type impurity has been implanted. In this process, annealing is performed such that the crystal defects 70 in the region where the p-type impurity has not been implanted are recovered, and a part of the crystal defects 72 in the region where the p-type impurity has been implanted remains. Hereinafter, in the semiconductor substrate 50, a region where the crystal defects remain (that is, the p-type region 62 and the n-type region 64) is referred to as a high crystal defect density region 80, and a region other than the high crystal defect density region 80 is referred to as a low crystal defect density region 82. Note that FIG. 7 is a top view of the semiconductor substrate 50 after the annealing has been performed. As shown in FIG. 7, the high crystal defect density region 80 is located in the central portion of the semiconductor substrate 50.

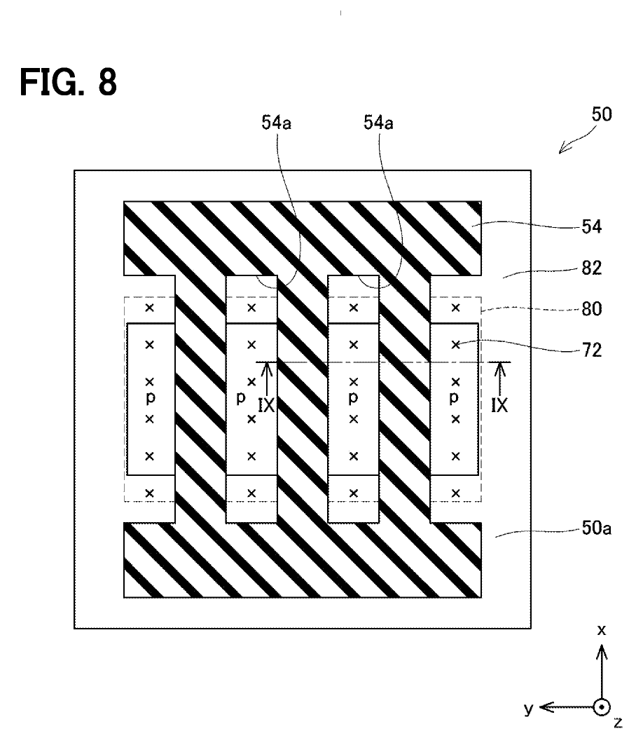

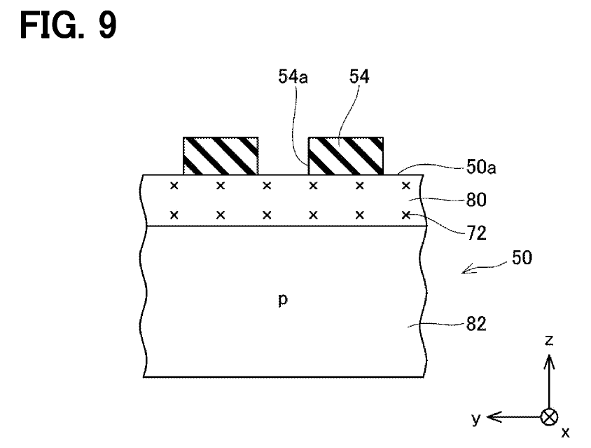

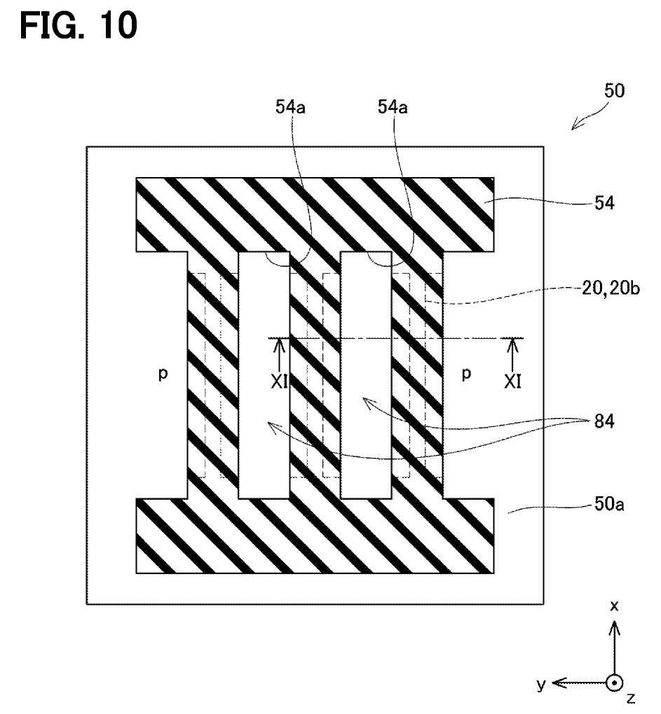

Next, as shown in FIGS. 8 and 9, a mask 54 having a plurality of openings 54a is formed on the upper surface 50a of the semiconductor substrate 50. The mask 54 is formed such that each opening 54a is located above the high crystal defect density region 80. Of the upper part of the high crystal defect density region 80, ranges where the fins 20 are to be formed are covered by the mask 54. The width of each opening 54a in the y-direction is adjusted to be equal to the interval between the wide portions 20a of adjacent fins 20 in FIG. 2.

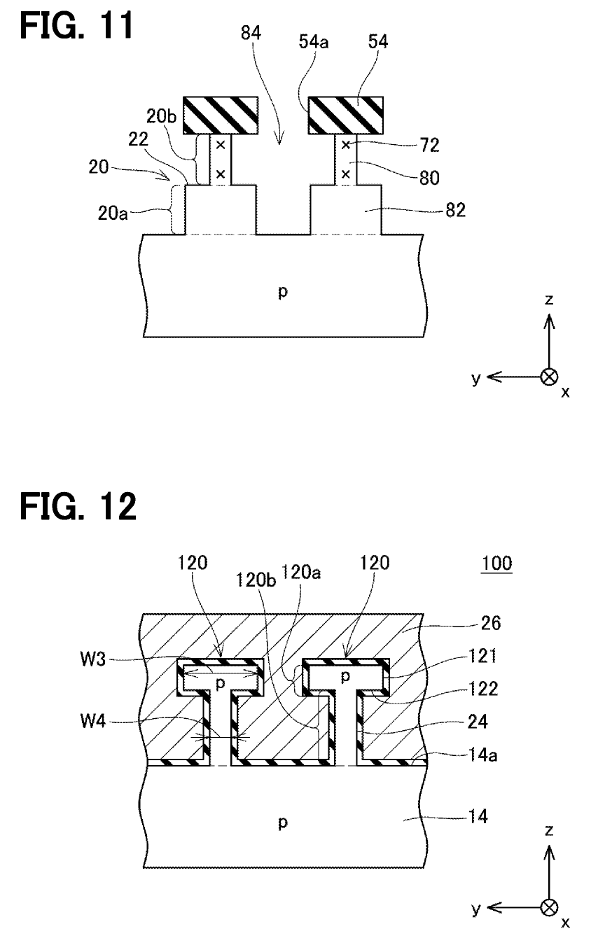

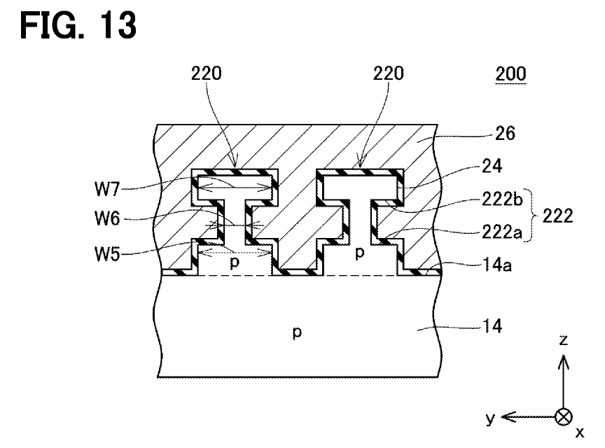

Next, as shown in FIGS. 10 and 11, the upper surface 50a of the semiconductor substrate 50 is etched through the openings 54a. Here, a depth range spanning the high crystal defect density region 80 and the low crystal defect density region 82 is etched. Specifically, the semiconductor substrate 50 is etched from its upper surface 50a to a depth corresponding to the upper surface 14a of the support layer 14 shown in FIG. 2. As a result, a plurality of recesses 84 are formed on the upper surface 50a of the semiconductor substrate 50. Since the crystal defects 72 are distributed in the high crystal defect density region 80, the etching rate is higher in the high crystal defect density region 80 than in the low crystal defect density region 82. For this reason, as shown in FIG. 11, in the depth range where the high crystal defect density region 80 exists, the width of the formed recess 84 becomes wider than in the depth range where the low crystal defect density region 82 exists. That is, as shown in FIGS. 10 and 11, in the depth range where the high crystal defect density region 80 exists, the semiconductor substrate 50 is etched to a range wider than the width of the opening 54a of the mask 54 in the y-direction. In other words, as shown in FIG. 11, in the depth range where the high crystal defect density region 80 exists, the width of the semiconductor region remaining between the plurality of recesses 84 becomes narrower than that in the depth range where the low crystal defect density region 82 exists. Each of these remaining semiconductor regions becomes the fin 20 shown in FIG. 2 and the like. In this manner, the fin 20 having the wide portion 20a and the narrow portion 20b with the step portion 22 as a boundary can be formed.

Thereafter, the gate insulating film 24, the gate electrode 26, the source electrode, the drain electrode, the insulating layer, and the like are formed by known methods. As a result, the semiconductor device 10 shown in FIGS. 1 to 3 is completed.

As described above, in this manufacturing method, the high crystal defect density region 80 is formed in the semiconductor substrate 50 such that the high crystal defect density region 80 and the low crystal defect density region 82 are arranged along the thickness direction of the semiconductor substrate 50. Then, by etching through the plurality of openings 54a, the plurality of recesses 84 are formed in a depth range spanning the high crystal defect density region 80 and the low crystal defect density region 82. The high crystal defect density region 80 has a higher etching rate compared to the low crystal defect density region 82. Therefore, in the depth range where the high crystal defect density region 80 exists, the width of the formed recess 84 becomes wider than in the depth range where the low crystal defect density region 82 exists. In other words, in the depth range where the high crystal defect density region 80 exists, the width of the fin 20 formed between the plurality of recesses 84 becomes narrower than in the depth range where the low crystal defect density region 82 exists. Thus, in the manufacturing method described above, using the boundary between the depth range where the high crystal defect density region 80 exists and the depth range where the low crystal defect density region 82 exists as the step portion 22, the fin 20 having different widths on the upper side and the lower side of the step portion 22 (that is, having the wide portion 20a and the narrow portion 20b) can be formed.

In the first embodiment described above, as described in the processes shown in FIGS. 4 to 6, the high crystal defect density region 80 is formed by implanting the n-type impurity and the p-type impurity into the semiconductor substrate 50 and annealing the semiconductor substrate 50. However, the method of forming the high crystal defect density region 80 is not limited to such a method. For example, a semiconductor substrate in which a p-type region and an n-type region are distributed in the same manner as in FIG. 6 may be manufactured by, for example, epitaxial growth or the like, and crystal defects may be selectively formed inside the semiconductor substrate by ion-implanting an inert element (for example, He or the like) into a range where crystal defects should be generated.

### Second Embodiment

A semiconductor device 100 of a second embodiment has a common configuration with the semiconductor device 10 of the first embodiment, except that the shape of a fin 120 is different. In the second embodiment, similar to the first embodiment, a step portion 122 is provided on a side surface 121 of the fin 120. In the second embodiment, the relationship of the width of the fin 120 between the upper side of the step portion 122 and the lower side of the step portion 122 is different from that of the first embodiment. In the second embodiment, a width W3 of the fin 120 from an upper end of the fin 120 to the step portion 122 is wider than a width W4 of the fin 120 from the step portion 122 to the upper surface 14a of the support layer 14. That is, in the second embodiment, the portion from the upper end of the fin 120 to the step portion 122 is a wide portion 120a, and the portion from the step portion 122 to the upper surface 14a of the support layer 14 is a narrow portion 120b.

The upper end portion of the fin 120 is easily deformed by thermal stress. However, in the second embodiment, since the width of the upper end portion of the fin 120 (that is, the wide portion 120a) is wide, the upper end portion has high strength against a force applied in the y-direction. Therefore, deformation of the fin 120 can be suppressed even if a large thermal stress is generated.

### Third Embodiment

A semiconductor device 200 of a third embodiment has a common configuration with the semiconductor device 10 of the first embodiment, except that the shape of a fin 220 is different. In the third embodiment, a side surface 221 of the fin 220 has two step portions 222. Hereinafter, the two step portions 222 are referred to as a first step portion 222a and a second step portion 222b, respectively, from the side closer to the upper surface 14a of the support layer 14.

In the third embodiment, a width W5 of the fin 220 from the upper surface 14a of the support layer 14 to the first step portion 222a is wider than a width W6 of the fin 220 between the first step portion 222a and the second step portion 222b. Further, the width W6 of the fin 220 between the first step portion 222a and the second step portion 222b is narrower than a width W7 of the fin 220 on the upper side of the second step portion 222b. The relationship between the width W5 and the width W7 is not particularly limited. The width W5 and the width W7 may be equal to each other, or one may be wider and the other narrower.

In this semiconductor device 200, the width of the fin 220 is wide at both the connection portion between the support layer 14 and the fin 220 and the upper end portion of the fin 220. Therefore, deformation of the fin 220 due to thermal stress can be further suppressed.

In the embodiments described above, the examples in which the number of step portions is one or two have been illustrated, but three or more step portions may be provided on the side surface of the fin. Further, in the embodiments described above, the cross-section of the fin (for example, the cross-section shown in FIG. 2) has a laterally symmetrical shape in the y-direction. However, the shape of the fin is not limited to the symmetrical shape as long as the widths of the fin located above and below the step portion are different via the step portion. The fin may have any shape in cross-section.

While only the selected exemplary embodiment and examples have been chosen to illustrate the present disclosure, it will be apparent to those skilled in the art from this disclosure that various changes and modifications can be made therein without departing from the scope of the disclosure as defined in the appended claims. Furthermore, the foregoing description of the exemplary embodiment and examples according to the present disclosure is provided for illustration only, and not for the purpose of limiting the disclosure as defined by the appended claims and their equivalents.

What is claimed is:

1. A semiconductor device comprising:
a semiconductor substrate having a support layer and a fin that protrudes from an upper surface of the support layer and extends along a predetermined direction;
a gate insulating film covering a surface of the fin; and
a gate electrode covering the gate insulating film, wherein
the fin has a step portion on a side surface of the fin, and
a width of the fin differs above and below the step portion.

2. The semiconductor device according to claim 1, wherein
the width of the fin at a portion between the upper surface of the support layer and the step portion is wider than the width of the fin at a portion above the step portion.

3. The semiconductor device according to claim 1, wherein
the width of the fin at a portion between an upper end of the fin and the step portion is wider than the width of the fin at a portion below the step portion.

4. The semiconductor device according to claim 1, wherein
the step portion includes a first step portion and a second step portion located above the first step portion, and
the width of the fin at a portion between the upper surface of the support layer and the first step portion is wider than the width of the fin at a portion between the first step portion and the second step portion, and the width of the fin at the portion between the first step portion and the second step portion is narrower than the width of the fin at a portion above the second step portion.

5. The semiconductor device according to claim 1, wherein
a minimum width of the fin is 300 nm or less.

6. A method for manufacturing a semiconductor device, comprising:
forming a high crystal defect density region having an increased crystal defect density in a specific depth range of a semiconductor substrate by ion-implanting an impurity from an upper surface of the semiconductor substrate into the specific depth range, so that a low crystal defect density region having a crystal defect density lower than that of the high crystal defect density region exists on at least one of an upper side and a lower side of the high crystal defect density region in the semiconductor substrate;
forming a mask having a plurality of openings on the upper surface of the semiconductor substrate so that each of the openings is located above the high crystal defect density region; and
forming a plurality of recesses in a depth range spanning the high crystal defect density region and the low crystal defect density region by etching the upper surface of the semiconductor substrate through the plurality of openings, so that a fin is formed between the plurality of recesses.
